(19) United States
(12) Patent Application Publication
(10) Pub. No.: US 2024/0405002 A1
(43) Pub. Date: Dec. 5, 2024

(54) SEMICONDUCTOR DEVICE ARRANGEMENT AND METHOD OF MANUFACTURING THE SAME

(71) Applicant: EPISTAR CORPORATION, Hsinchu (TW)

(72) Inventors: Min-Hsun HSIEH, Hsinchu (TW); Chang-Tai HSIAO, Hsinchu (TW)

(21) Appl. No.: 18/734,838

(22) Filed: Jun. 5, 2024

Related U.S. Application Data
(60) Provisional application No. 63/471,080, filed on Jun. 5, 2023.

(51) Int. Cl. H01L 25/075; H01L 23/00

(52) U.S. Cl. CPC H01L 25/0753; H01L 24/32; H01L 2224/32225; H01L 2924/381

(57) ABSTRACT

An embodiment of the present disclosure provides a semiconductor device arrangement. This semiconductor device arrangement includes a substrate and a plurality of semiconductor devices. The substrate includes an upper surface. The plurality of semiconductor devices is separately and staggered located on the upper surface, and includes a first semiconductor device and a second semiconductor device. Wherein the first semiconductor device includes a first interior angle, the second semiconductor device includes a second interior angle, and there is a minimum distance between the first interior angle and the second interior angle among the plurality of semiconductor devices, wherein the minimum distance is between 3 μm 25 μm.

This application claims priority to the benefit of U.S. Provisional Patent Application No. 63/471,080 filed on Jun. 5, 2023 and the entire content of which is hereby incorporated by reference herein in its entirety.

### TECHNICAL FIELD

The present disclosure relates to a semiconductor device arrangement, and more particularly, to a light-emitting diode device arrangement and a method of manufacturing the same.

### DESCRIPTION OF BACKGROUND ART

A light-emitting diode (LED) is a semiconductor device that is suitable for diverse lighting and display applications because it has good characteristics, such as low power consumption, long operation life, shock tolerance, a compact size, and swift response.

As the continuous advancements in LED technology, the brightness of an LED die is increased continuously, and the size of LED die is also gradually being reduced to, e.g., less than 100 μm, 50 μm, or 30 μm. The use of LED dies is no longer limited to general lighting applications or as a backlight source in LCD monitors. To use LED dies directly as the pixels of an LED display could become a trend in next-generation displays.

An LED display is composed of millions or even tens of millions of LED chips. Precisely placing such a large number of LED dies on a display panel requires fast and reliable die transfer technology. In addition, there is a need to produce a semiconductor device arrangement with high area utilization efficiency and high yield for subsequent chip transfer processes.

### SUMMARY OF THE APPLICATION

According to one embodiment of the present disclosure, a semiconductor device arrangement is provided. This semiconductor device arrangement includes a substrate and a plurality of semiconductor devices. The substrate includes an upper surface. The plurality of semiconductor devices is separately and staggered located on the upper surface, and includes a first semiconductor device and a second semiconductor device. Wherein the first semiconductor device includes a first interior angle, the second semiconductor device includes a second interior angle, and there is a minimum distance between the first interior angle and the second interior angle among the plurality of semiconductor devices, wherein the minimum distance is between 3 μm 25 μm.

### BRIEF DESCRIPTION OF THE DRAWINGS

The embodiments of the present disclosure may be more fully understood by reading the subsequent detailed description and examples with references made to the accompanying drawings. In addition, for clarity, the features in the drawings may not be drawn to actual scale, so some features in some drawings may be deliberately enlarged or reduced in size, wherein:

FIG. 1A illustrates a top view of a semiconductor device arrangement in accordance with one embodiment of the present disclosure;

FIG. 1B illustrates is a cross-sectional view taken along line A-A′ of FIG. 1A;

FIG. 1C illustrates is a cross-sectional view taken along line B-B′ of FIG. 1A;

FIG. 2A illustrates a top view of a semiconductor device arrangement undergoing a non-contact mode laser transfer process in accordance with one embodiment of the present disclosure;

FIG. 2B illustrates is a cross-sectional view of a plurality of semiconductor devices being transferred to another carrier along line C-C′ of FIG. 2A;

FIG. 2C illustrates a cross-sectional view of a plurality of semiconductor devices being transferred to another carrier along line D-D′ of FIG. 2A;

FIG. 3 illustrates a regional enlarged view of a semiconductor device arrangement in accordance with another embodiment of the present disclosure;

FIG. 4A illustrates a top view of a semiconductor device arrangement in accordance with another embodiment of the present disclosure;

FIG. 4B illustrates a cross-sectional view taken along line E-E′ of FIG. 4A;

FIG. 4C illustrates a cross-sectional view taken along line F-F′ of FIG. 4A;

FIG. 4D illustrates an enlarged view of region P in FIG. 4A;

FIG. 5 illustrates a regional enlarged view of a semiconductor device arrangement in accordance with another embodiment of the present disclosure;

FIGS. 6A-6C are schematic views of various stages in a method of manufacturing semiconductor device arrangement in accordance with an embodiment of the present disclosure;

FIG. 7A illustrates a top view of a semiconductor device arrangement in accordance with one embodiment of the present disclosure;

FIG. 7B illustrates a cross-sectional view taken along line G-G′ of FIG. 7A;

FIG. 7C illustrates a cross-sectional view taken along line H-H′ of FIG. 7A;

FIG. 7D illustrates an enlarged view of region P′ in FIG. 7A;

FIG. 8A illustrates a regional enlarged view of a semiconductor device arrangement in accordance with another embodiment of the present disclosure;

FIG. 8B illustrates a regional enlarged view of a semiconductor device arrangement in accordance with another embodiment of the present disclosure.

### DETAILED DESCRIPTION OF THE APPLICATION

The semiconductor device arrangements and manufacturing methods thereof in accordance with the embodiments of the present disclosure are described in detail in the following description. It should be understood that in the following detailed description, for purposes of explanation, numerous specific details and embodiments are set forth in order to provide a thorough understanding of the present disclosure. The elements and configurations described in the following detailed description are set forth in order to clearly describe the present disclosure. The embodiments are used merely for the purpose of illustration. In addition, the drawings of different embodiments may use like and/or corresponding numerals to denote like and/or corresponding elements in order to clearly describe the present disclosure. However, the use of like and/or corresponding numerals in the drawings of different embodiments does not suggest any correlation between different embodiments.

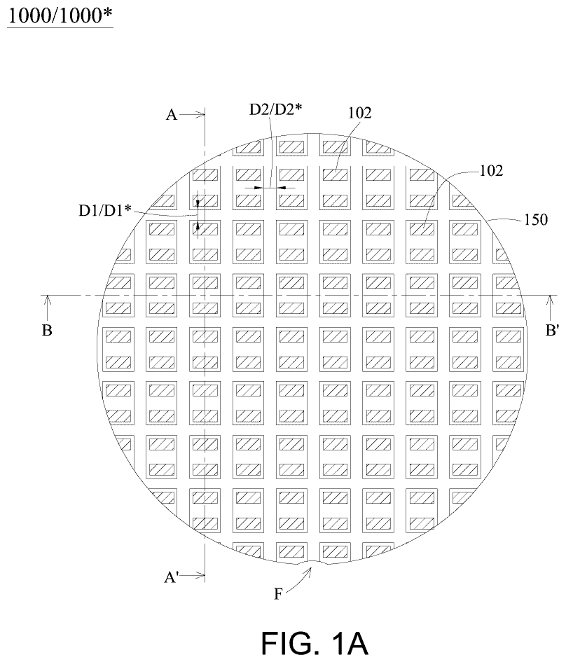

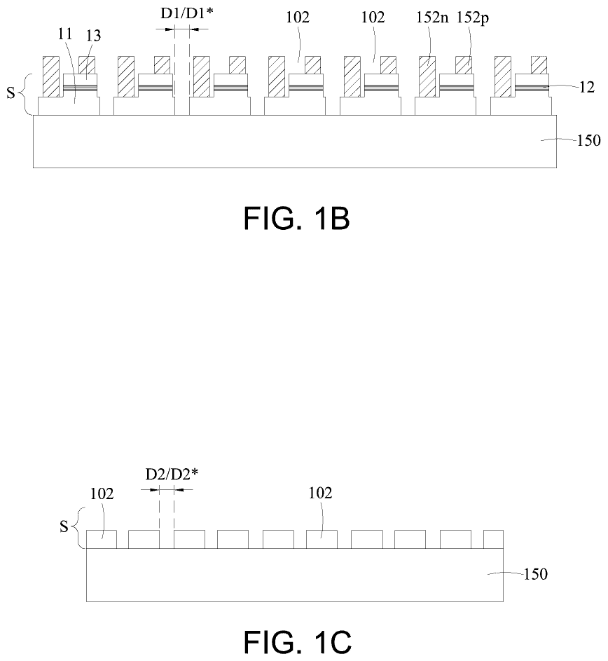

FIG. 1A is a top view of a semiconductor device arrangement 1000 in accordance with an embodiment of the present disclosure. The semiconductor device arrangement 1000 includes a plurality of semiconductor devices 102 arranged in an array on a growth substrate 150. There is vertical or horizontal distance between any two adjacent semiconductor devices 102 which are adjacent to each other by respective parallel sides, wherein the vertical or horizontal distance is a fixed value. In the array, there is no vacancy and is filled with semiconductor devices 102. The semiconductor device 102 may be a light-emitting diode (LED), a laser diode (LD), transistor, or an integrated circuit chip (IC chip). The material of the growth substrate 150 includes but is not limited to germanium (Ge), gallium arsenide (GaAs), indium phosphide (InP), sapphire, silicon carbide (SiC), silicon (Si), lithium aluminate (LiAlO₂), zinc oxide (ZnO), gallium nitride (GaN), aluminum nitride (AlN), and other materials suitable for semiconductor devices to epitaxial growth. In FIG. 1A, the semiconductor devices 102 are formed in an array on the growth substrate 150, but some of the semiconductor devices 102 at the edge of the growth substrate 150 do not have a complete structure. In another embodiment, all the semiconductor devices 102 on the growth substrate 150 have complete structures (not shown). In FIG. 1A, the growth substrate 150 is circular, with a flat edge F below for orientation identification. In another embodiment, the growth substrate 150 may also be square or other shapes depending on the requirements.

FIG. 1B is a cross-sectional view taken along line A-A′ of FIG. 1A. FIG. 1C is a cross-sectional view taken along line B-B′ of FIG. 1A. In FIG. 1B, a plurality of semiconductor devices is epitaxially formed on the growth substrate 150. In one embodiment, the semiconductor element 102 is an LED and includes a semiconductor stack S, and the positive electrode 152p and the negative electrode 152n are respectively arranged on top of the semiconductor stack S. The semiconductor stack S sequentially includes a first semiconductor layer 11, an active layer 12, and a second semiconductor layer 13 on the growth substrate 150. The first semiconductor layer 11 and the second semiconductor layer 13 provide electrons and electric holes respectively so that the electrons and electric holes are recombined in the active layer 12 to emit light. The first semiconductor layer 11, the active layer 12, and the second semiconductor layer 13 may contain III-V groups semiconductor material, such as AlₓIn_{y}Ga_{(1-x-y)}N or AlₓIn_{y}Ga_{(1-x-y)}P, where 0≤x, y≤1, (x+y)≤1. According to the material of the active layer 12, the semiconductor device 102 can emit a red light with a peak wavelength between 610 nm and 650 nm, a green light with a peak wavelength between 530 nm and 570 nm, a cyan light with a peak wavelength between 485 nm and 500 nm, a blue light with a peak wavelength between 450 nm and 485 nm, a violet light with a peak wavelength between 400 nm and 450 nm, or a ultraviolet light with a peak wavelength between 280 nm and 400 nm. The maximum thickness of semiconductor stack S is about equal to or less than 10 μm. The materials of positive and negative electrodes 152p and 152n include metals such as gold (Au), silver (Ag), copper (Cu), chromium (Cr), aluminum (Al), platinum (Pt), nickel (Ni), titanium (Ti), or their alloys, or their lamination.

Referring to both FIGS. 1A and 1B, any two adjacent semiconductor devices 102 have an equal vertical distance D1 in the direction parallel to line A-A′. Referring to both FIGS. 1A and 1C, there is an equal horizontal distance D2 in the direction parallel to line B-B′ between any two adjacent semiconductor devices 102. As shown in FIG. 1A, because the total surface area of the growth substrate 150 is fixed, the surface area used to form the semiconductor devices 102 thereon is restricted by the vertical distance D1 and the horizontal distance D2. When the vertical and horizontal distances D1 and D2 are smaller, the surface area of the growth substrate 150 available for the semiconductor devices 102 is larger, and the area utilization efficiency of the growth substrate 150 is improved.

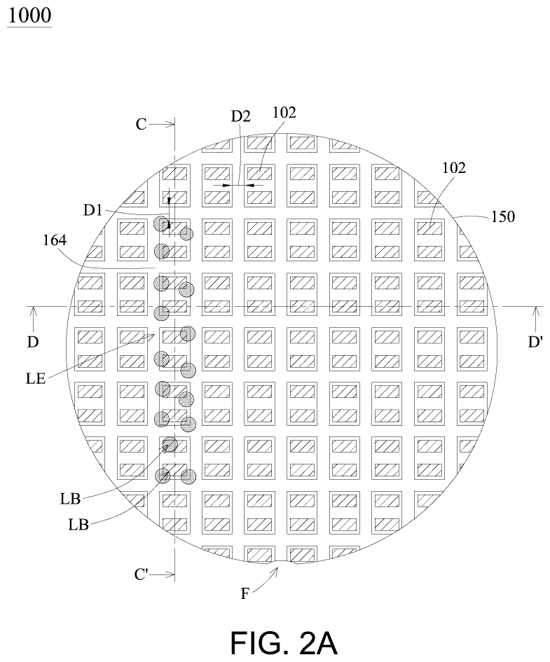

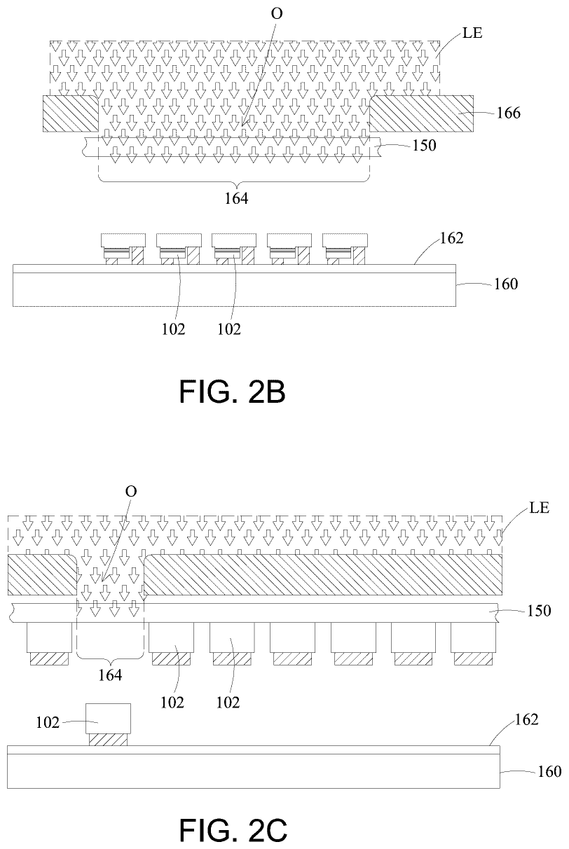

FIG. 2A is a view of a semiconductor device arrangement undergoing a non-contact mode laser transfer process in accordance with one embodiment of the present disclosure. The semiconductor device arrangement 1000 has a predetermined exposure area 164 on the growth substrate 150. As shown in the figure, several semiconductor devices 102 in the predetermined exposure area 164 are transferred to another carrier (not shown) after irradiated by a laser energy LE.

FIG. 2B is a cross-sectional view of a semiconductor device 1 taken along line C-C′ of FIG. 2A. As shown in the figure, the semiconductor device 102 does not directly contact the target carrier (carrier 160) when the laser energy LE is irradiated during the non-contact laser transfer process. Several semiconductor devices 102 in the predetermined exposure area 164 are irradiated by laser energy LE, detached from the growth substrate 150, and fall downwardly onto the adhesive layer 162 of another carrier 160. FIG. 2C is a cross-sectional view of a semiconductor device 1 taken along line D-D′ of FIG. 2A. A semiconductor device 102 in the predetermined exposure area 164 is irradiated by laser energy LE, detached from the growth substrate 150, and fall downwardly onto the adhesive layer 162 of another carrier 160. Referring to FIGS. 2A, 2B, and 2C, in one embodiment, the laser energy LE is formed by the aggregation of multi-shot laser beams LB. That is, a semiconductor device 102 is irradiated by multi-shot laser beams LB during an irradiation process. In another embodiment, the laser energy LE may be composed of a single-shot laser beam LB. That is, multiple semiconductor devices 102 are irradiated by only one laser beam LB in one irradiation process. In one embodiment, the projection area and position of the predetermined exposure area 164 can be determined by a mask 166 arranged above the semiconductor device arrangement 1000. The mask 166 may include a translucent substrate (not shown, e.g., glass, quartz, sapphire) and a light-shielding metal layer (e.g., gold, chromium, tungsten) located thereon. The mask 166 has an opening O, and the projection area of the opening O corresponds to the area of the predetermined exposure area 164. When the laser transfer step is performed, the semiconductor device 102 other than the predetermined exposure area 164 is not irradiated, not detached from the growth substrate 150, and remains on the growth substrate 150 because the mask 166 blocks the laser energy LE.

In FIGS. 2B and 2C, the carrier 160 may be a carrier to support the semiconductor devices 102, and its composition may include but is not limited to germanium (Ge), gallium arsenide (GaAs), phosphorus indium (InP), sapphire (Sapphire), silicon carbide (SiC), silicon (Si), lithium aluminate (LiAlO₂), zinc oxide (ZnO), gallium nitride (GaN), aluminum nitride (AlN), metal with supporting capacity, glass, thermal release tape, UV release tape, chemical release tape, heat-resistant tape, blue tape, or tape with a dynamic release layer (DRL). The adhesive layer 162 may be composed of polymers, for example, polyimide (PI), acrylic resin, epoxide resin (EPO), polybenzoxazole (PBO), polysiloxane, cyclic olefin polymer (COP), or benzocyclobutane (BCB).

In the aforementioned non-contact laser transfer process, in order to make the laser energy LE evenly and accurately irradiate the semiconductor devices 102 to be transferred, as shown in FIGS. 2B and 2C, the width of the exposure area 164 (shown as the arrows in the figure) is larger than the overall width of the semiconductor device 102 to be transferred, so that the tolerance to the alignment error of the mask 166 may be improved. In addition, in the non-contact laser transfer process, the area where the semiconductor device 102 is close to the growth substrate 150 will generate gas due to under the irradiation of the laser energy LE. For example, when the first semiconductor layer 11 is gallium nitride (GaN) and is irradiated by laser energy LE, it decomposes to produce nitrogen (N₂) and gallium (Ga) particles. It needs sufficient space/distance between two adjacent semiconductor devices 102 to allow the generated gas to be discharged, so as to prevent the semiconductor device 102 from changing its direction of travel due to unbalanced airflow disturbance during the fall down process, and then falling on the incorrect position of the adhesive layer 162.

In an embodiment, the minimum distance between two adjacent semiconductor devices 102 that can be applied to a non-contact laser transfer process is about 3 microns (μm). Based on the parameters of the transfer process, the accuracy of the equipment, and the requirement of the semiconductor device arrangement, the vertical distance D1 or the horizontal distance D2 can be equal to or larger than 3 μm, for example, 3 μm, 4 μm, 6 μm, 9 μm, 15 μm, 20 μm, or 25 μm, and the vertical distance D1 and the horizontal distance D2 can be equal or unequal. When the vertical of the horizontal distance is greater than 25 μm, the area utilization efficiency of the growth substrate 150 is decreased.

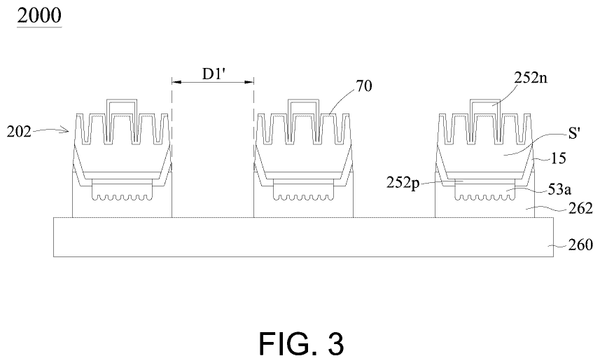

FIG. 3 is a regional enlarged view of a semiconductor device arrangement in accordance with another embodiment of the present disclosure. The top view of the semiconductor device arrangement 2000 may be referred to FIG. 1A. As shown in FIG. 3, a plurality of semiconductor devices 202 is arranged on a carrier 260 with a plurality of sub-adhesive layers 262, wherein one semiconductor device 202 corresponds to one sub-adhesive layer 262. The semiconductor device 202 includes a semiconductor stack S′, a positive electrode 252p, a negative electrode 252n, a protective layer 15 covering a part of the outer surface of the semiconductor stack S′, and a first bonding pad 53a formed under the positive electrode 252p by electroplating, chemical plating, or evaporation. The positive electrode 252p and the first bonding pad 53a are located below the semiconductor stack S′ and embedded in the sub-adhesive layer 262. The negative electrode 252n is located above the semiconductor stack S′. In other words, the positive electrode 252p (first bonding pad 53a) and the negative electrode 252n of the semiconductor device 202 are located on opposite sides of the semiconductor stack S′. In addition, the upper surface of the semiconductor stack S′ may be optionally coated with a light-translucent conductive layer 70 (e.g., indium tin oxide; ITO) to improve the current diffusion performance of the upper surface of the semiconductor device 202. As shown in the figure, there is a minimum distance D1′ between two sides of the adjacent semiconductor devices 202.

In one embodiment, the semiconductor device 202 is LED. The semiconductor stack S′ includes a first semiconductor layer (not shown), an active layer (not shown), and a second semiconductor layer (not shown). The first semiconductor layer, the active layer, and the second semiconductor layer may contain III-V groups semiconductor materials, such as AlₓIn_{y}Ga_{(1-x-y)}N or AlₓIn_{y}Ga_{(1-x-y)}P, wherein 0≤x, y≤1, (x+y)≤1. According to the material of the active layer, the semiconductor device 202 can emit red light with a peak wavelength between 610 nm and 650 nm, green light with a peak wavelength between 530 nm and 570 nm, cyan light with a peak wavelength between 485 nm and 500 nm, blue light with a peak wavelength between 450 nm and 485 nm, violet light with a peak wavelength between 400 nm and 450 nm, or ultraviolet light with a peak wavelength between 280 nm and 400 nm. The maximum thickness of semiconductor stack S is about equal to or less than 10 μm. The materials of positive and negative electrodes 152p and 152n may include metals, such as gold (Au), silver (Ag), copper (Cu), chromium (Cr), aluminum (Al), platinum (Pt), nickel (Ni), titanium (Ti), or their alloys, or a stack thereof. The material of bonding pad 53a may contain a metal with a low melting point or an alloy with a low liquidus melting point (compared to the materials of positive and negative electrodes 252p and 252n) with a melting point or liquidus melting point below 210° C. The material of the bonding pad 53a is, for example, bismuth (Bi), tin (Sn), indium (In), or an alloy thereof. In one embodiment, the melting point or an alloy with a low liquidus melting point is lower than 170° C., wherein the material of the low liquidus melting point alloy may be tin-indium alloy or tin-bismuth alloy. The materials of the carrier 260 and the sub-adhesive layer 262 may refer to the aforementioned relevant paragraphs.

In an embodiment, a single sub-adhesive layer 262 corresponds to a single semiconductor device 202. In another embodiment, a single adhesive layer (not shown) corresponds to a plurality of semiconductor devices 202. For example, a single adhesive layer covers all or part of the upper surface of the carrier 260 and supports all or part of the semiconductor devices 202. In an embodiment, the semiconductor devices 202 in the semiconductor device arrangement includes a positive electrode 152p and a negative electrode 152n located on the same side of the semiconductor stack S. As aforementioned, the minimum distance between two adjacent semiconductor devices 202 that can be applied to a non-contact laser transfer process is about 3 micrometers (μm). Based on the parameters of the transfer process, the accuracy of the equipment, and the requirement of the semiconductor device arrangement, the minimum distance D1′ can be equal to or larger than 3 μm, for example, 3 μm, 4 μm, 6 μm, 9 μm, 15 μm, 20 μm, or 25 μm.

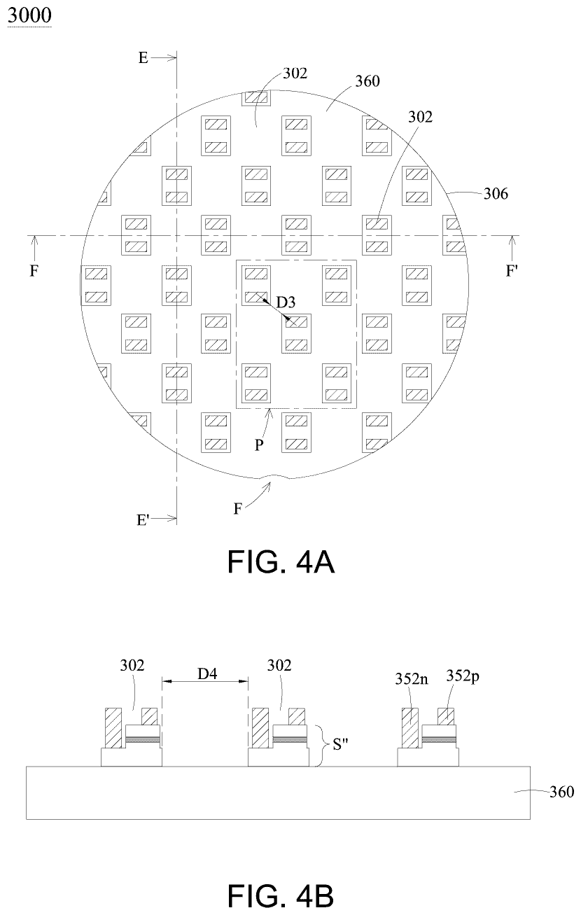

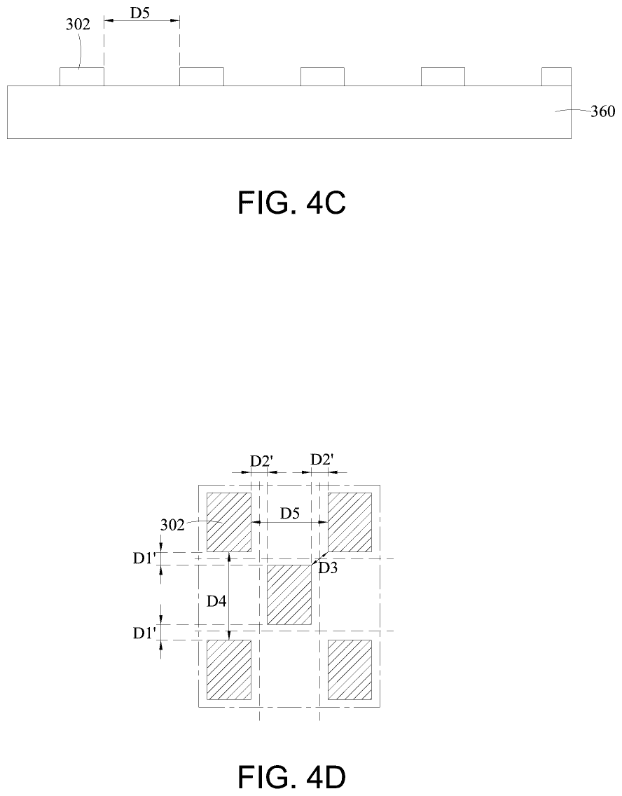

FIG. 4A shows a top view of another semiconductor device arrangement 3000 in the present disclosure. The semiconductor device arrangement 3000 includes a plurality of semiconductor devices 302 arranged on a carrier 360 in a staggered manner, and the vertical or horizontal distance between any two adjacent semiconductor devices 302 is a fixed value. FIG. 4B is a cross-sectional view taken along line E-E′ of FIG. 4A, FIG. 4C is a cross-sectional view taken along line F-F′ of FIG. 4A, and FIG. 4D is an enlarged view of area P in FIG. 4A. In FIG. 4D, in order to simplify the drawing, the semiconductor device 302 shows only the outer contour and omits the other components. The structure of the semiconductor device 302 may refer to the figures and paragraphs related to semiconductor devices 102 and 202 mentioned above.

In FIGS. 4B and 4C, a plurality of semiconductor devices 302 is formed on the carrier 360, and the semiconductor device 302 includes a semiconductor stack S″, a positive electrode 352p and a negative electrode 352n respectively arranged on the semiconductor stack S″. There is a vertical distance D4 between two adjacent semiconductor devices 302 in the direction parallel to line E-E′, and there is a horizontal distance D5 between two adjacent semiconductor devices 302 in the direction parallel to line F-F′. In an embodiment, the carrier 360 can be a growth substrate of the semiconductor device 302, and a plurality of semiconductor devices 302 is epitaxially formed on the carrier 360. In another embodiment, the carrier 360 may be a carrier for supporting the semiconductor devices 302, which has an adhesive layer (not shown) arranged on the upper surface thereof, and a plurality of semiconductor devices 302 is arranged on the adhesive layer. The materials of the carrier 360 and the adhesive layer may refer to the relevant paragraphs of the preceding carrier 160, and the material of the adhesive layer can refer to the aforementioned relevant paragraphs. In one embodiment, a single adhesive layer corresponds to a single semiconductor device 302. In another embodiment, a plurality of semiconductor devices 302 is located on a single adhesive layer. For example, a single adhesive layer covers all or part of the carrier 360 and supports all or part of the semiconductor devices 202.

As shown in FIG. 4D, a plurality of semiconductor devices 302 is arranged on a carrier 360 in a staggered manner, the vertical or horizontal distance between any two adjacent semiconductor devices 302 is a fixed value, and the minimum distance D3 between the semiconductor devices 302 is located between the interior angles of the two obliquely adjacent semiconductor devices 302. As shown in FIG. 4D, the five semiconductor devices 302 are arranged in a staggered manner, and each of the semiconductor devices 302 has four interior angles. Among the plurality of semiconductors 302, the minimum distance between two adjacent semiconductor devices is D3. As shown in FIG. 4D, and the minimum distance D3 is between the lower left interior angle of the semiconductor device 302 at the upper right corner and the upper right interior angle of the semiconductor device 302 at center, and D3 is 3˜25 μm. There is also a minimum distance D3 between the lower right interior angle of the semiconductor device 302 at the upper left corner and the upper left interior angle of the semiconductor device 302 at center (not shown).

Referring to FIG. 4D, the vertical distance D4 between two adjacent semiconductor devices 302 is equivalent to the length of one semiconductor device 302 plus two vertical distances D1′. The horizontal distance D5 between two adjacent semiconductor devices 302 is equivalent to the width of one semiconductor device 302 plus two horizontal distances D2′.

As shown in FIG. 4D, if the contour of the interior angle of the semiconductor device 302 is arc-shaped, the minimum distance D3 between two semiconductor devices 302 which are obliquely adjacent to each other may be increased compared with the situation when the semiconductor devices 302 with right-angle interior angles contour.

In an embodiment, the carrier 360 is circular with a flat edge F for orientation identification. In another embodiment, the carrier 360 may also be square or other shapes. The semiconductor device 302 is a structure with a positive electrode 352p and a negative electrode 352n located on the same side of the semiconductor stack S″. In another embodiment, electrodes 3a and 3b of the semiconductor device 302 are located on opposite sides of the semiconductor stack S″ (not shown), and the structure thereof may be referred to the figures and related paragraphs of the aforementioned semiconductor device 202.

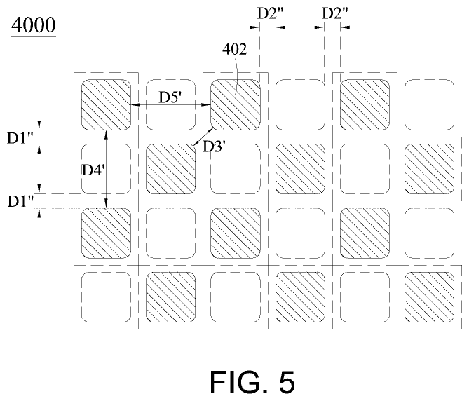

FIG. 5 shows a regional enlarged top view of a semiconductor device arrangement in another embodiment of the present disclosure. In an embodiment, the semiconductor device arrangement 4000 includes a plurality of semiconductor devices 402 with square outer contours arranged on a carrier (not shown) in a staggered manner. In one embodiment, the vertical distance D4′ and the horizontal distance D5′ of two adjacent semiconductor devices 402 are equal. The vertical distance D4′ is equivalent to the length of a semiconductor device 402 plus two vertical distances D1″, and the horizontal distance D5′ is equivalent to the width of a semiconductor device 402 plus two horizontal distances D2″, and D1″ is equal to D2″.

In an embodiment, a plurality of semiconductor devices 402 is arranged equidistantly on a carrier in a staggered manner (not shown). Among the plurality of semiconductors 402, the minimum distance between two adjacent semiconductor devices 402 is D3′, and the minimum distance D3′ is between the interior angles of two semiconductor devices 402 which are obliquely adjacent to each other. In order to increase the minimum distance D3′, the contour of the interior angle of the semiconductor device 402 is rounded. In addition, in another embodiment, in the top view, in addition to the square shape, the contour of semiconductor devices 402 may be of other shapes, such as circles or parallelograms.

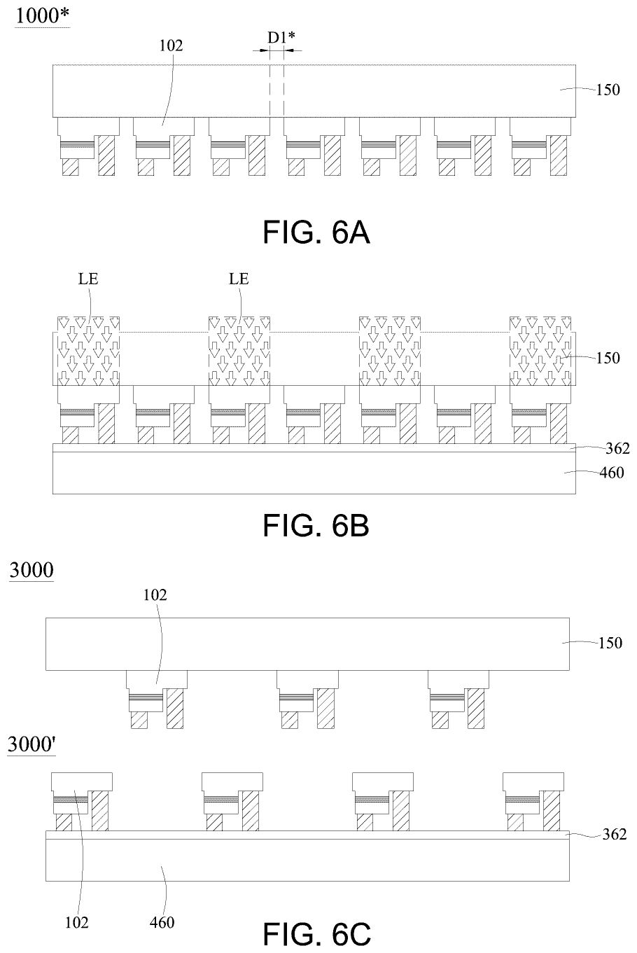

FIGS. 6A-6C show schematic views of various stages in a method of manufacturing a semiconductor device arrangement. As shown in FIG. 6A, a semiconductor device arrangement 1000* is provided. The structure of the semiconductor device arrangement 1000* may be referred to FIGS. 1A-1C and related paragraphs. The semiconductor device arrangement 1000* includes a plurality of semiconductor devices 102 epitaxially formed in an array on a growth substrate 150, wherein the vertical distance between two adjacent semiconductor devices 102 in the vertical direction is D1* (as shown in FIG. 1B), and the horizontal distance between the two adjacent semiconductor devices 102 in the horizontal direction is D2* (as shown in FIG. 1C).

Then, as shown in FIG. 6B, a carrier 460 with an adhesive layer 362 on the surface thereof and a semiconductor device arrangement 1000* are provided in a face-to-face configuration. The semiconductor device arrangement 1000* faces the carrier 460 with the side where the plurality of semiconductor devices is arranged to the side of the carrier where the adhesive layer 362 is arranged, and therefore the plurality of semiconductor devices 102 arranged in an array on the growth substrate 150 is in direct contact with the adhesive layer 362. Next, a laser energy LE is selectively applied to the semiconductor devices 102 to be transferred for a contact mode laser transfer process (laser lift off process, LLO). In the contact mode laser transfer process, one ends of the semiconductor devices 102 are connected to the growth substrate 150, while the opposite ends thereof are in direct contact with the adhesive layer 362. The semiconductor devices 102 are in direct contact with the growth substrate 150 and the adhesive layer 362 respectively so that the positions of the semiconductor devices 102 on the carrier 460 are not altered easily by the gas generated during the contact mode laser transfer process. In one embodiment, in the semiconductor device arrangement 1000*, the vertical distance D1* and horizontal distance D2* may be less than 3 μm. The materials of the carrier 460 and the adhesive layer 362 may be referred to the aforementioned relevant paragraphs.

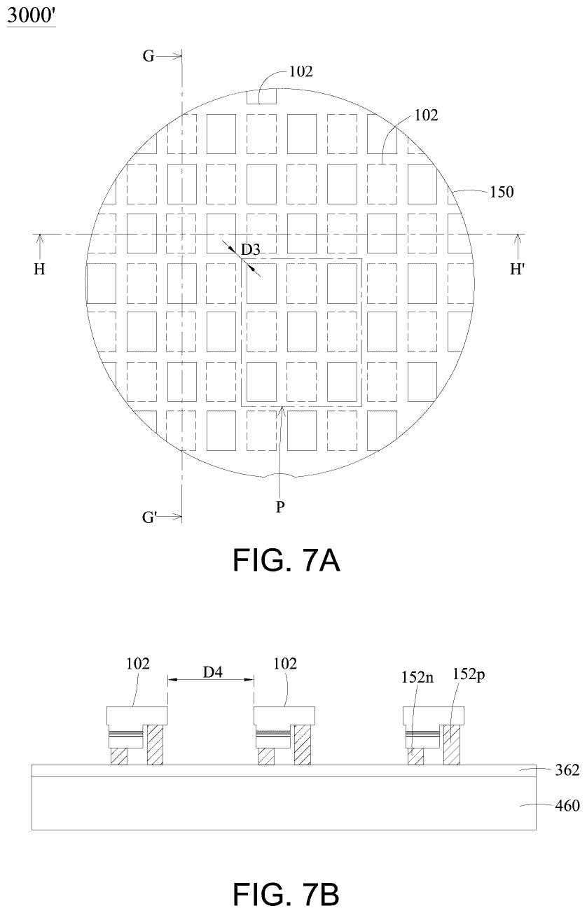

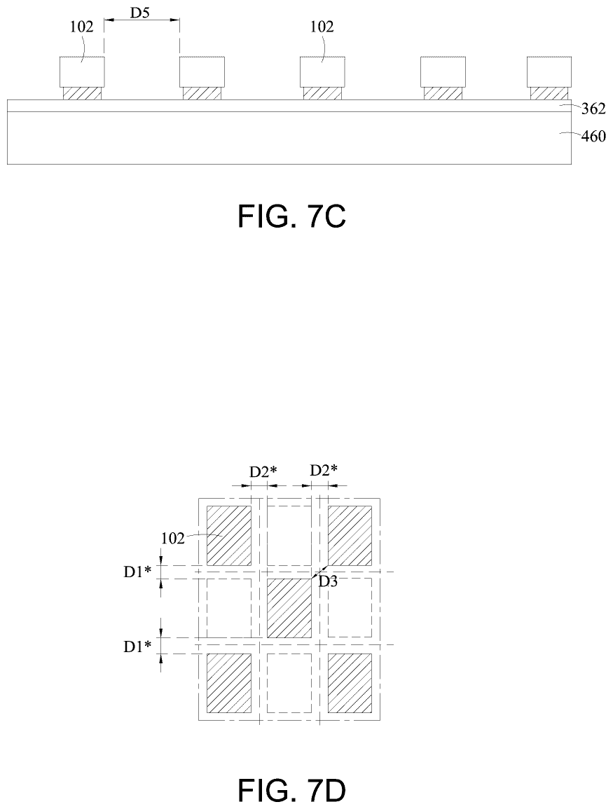

As shown in FIG. 6C, the growth substrate 150 is separated from the carrier 460. After the laser irradiation, a part of the semiconductor devices 102 are transferred from the growth substrate 150 to the adhesive layer 362 of the carrier 460 to form a semiconductor device arrangement 3000′, while the other part of the semiconductor devices 102 remaining on the growth substrate 150 forms semiconductor device arrangement 3000. In one embodiment, in a top view, the semiconductor devices 102 in the semiconductor device arrangement 3000′ and the semiconductor devices 102 in the semiconductor device arrangement 3000 are arranged in staggered patterns respectively. The structure of the semiconductor device arrangement 3000 may be referred to FIGS. 4A-4C and related paragraphs, and the structures of the semiconductor device arrangement 3000 may be referred to FIGS. 7A-7C and related paragraphs.

In FIG. 6C, after some semiconductor devices 102 are transferred from the growth substrate 150 to the adhesive layer 362 of the carrier 460, the minimum distance between two adjacent semiconductor devices 102 in the semiconductor device arrangement 3000/3000′ is located between the interior angles of the two adjacent semiconductor devices which are obliquely adjacent to each other as the minimum distance D3 in FIGS. 4A and 7A.

FIG. 7A shows a top view of the semiconductor device arrangement 3000′, in which the solid line portion represents the position of the transferred semiconductor devices 102. FIGS. 7B and 7C respectively show cross-sectional views along line G-G′ and line H-H′ in FIG. 7A. FIG. 7D shows a regional enlarged view of area P shown in FIG. 7A. As shown in FIG. 7D, the minimum distance D3 is larger than the vertical distance D1* and the horizontal distance D2*. If the interior angle of the semiconductor device 102 has an arc-shaped contour and the minimum distance D3 remains unchanged, for example, 3 μm, compared to the case where the contour of the interior angle of the semiconductor device 102 is a right angle, the vertical distance D1* and horizontal distance D2* can be further reduced. Therefore, when the area is the same, the semiconductor device arrangement 1000* may include more semiconductor devices 102.

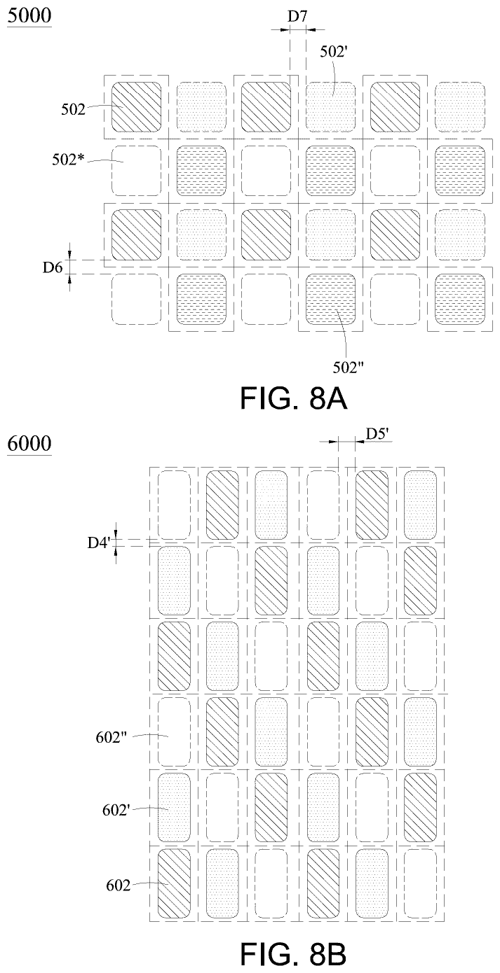

FIG. 8A is a top view of a partial semiconductor device arrangement according to another embodiment of the present disclosure. The semiconductor device arrangement 5000 is similar with the aforementioned semiconductor device arrangement 1000/1000*. A plurality of semiconductor devices 502, 502′, 502″, and 502* marked with the different background colors is arranged in an array on a carrier (no shown). In the figure, the semiconductor devices 502 are designated as a first group, the semiconductor devices 502′ are designated as a second group, the semiconductor devices 502″ are designated as a third group, and the semiconductor devices 502* are designated as a fourth group. The semiconductor devices 502, 502′, 502″, and 502* may be epitaxially grown on the carrier or fixed on the carrier through an adhesive layer. The details thereof may be referred to the aforementioned figures and paragraphs related to the semiconductor device 102 or 202. The number of each group of semiconductor devices 502, 502′, 502″, and 502* is approximately one quarter of the total number of all semiconductor devices on the semiconductor device arrangement 5000. Taking advantage of the semiconductor device arrangement 5000, the semiconductor devices 502, 502′, 502″, and 502* may be respectively transferred by contact mode laser transfer processes to different substrates to form different sub-semiconductor device arrangements for the application of the following non-contact mode laser transfer process. For example, the semiconductor devices 502 are collectively transferred as a group to a first substrate (not shown) to form a first sub-semiconductor device arrangement (not shown), the semiconductor devices 502′ are collectively transferred as a group to a second substrate (not shown) to form a second sub-semiconductor device arrangement (not shown), the semiconductor devices 502″ are collectively transferred as a group to a third substrate (not shown) to form a third sub-semiconductor device arrangement (not shown), and the semiconductor devices 502* are left on the original carrier to form a fourth sub-semiconductor device arrangement (not shown). In the first sub-semiconductor device arrangement, the semiconductor devices 502 are equidistantly separated from one another with a fixed vertical distance equal to a length of one semiconductor device 502 plus two vertical distances D6 and a fixed horizontal distance equal to a width of one semiconductor device 502 plus two horizontal distances D7. In the second sub-semiconductor device arrangement, the semiconductor devices 502′ are equidistantly separated from one another with a fixed vertical distance equal to a length of one semiconductor device 502′ plus two vertical distances D6 and a fixed horizontal distance equal to a width of one semiconductor device 502′ plus two horizontal distances D7. In the third sub-semiconductor device arrangement, the semiconductor devices 502″ are equidistantly separated from one another with a fixed vertical distance equal to a length of one semiconductor device 502″ plus two vertical distances D6 and a fixed horizontal distance equal to a width of one semiconductor device 502″ plus two horizontal distances D7. In the fourth sub-semiconductor device arrangement, the semiconductor devices 502* are equidistantly separated from one another with a fixed vertical distance equal to a length of one semiconductor device 502* plus two vertical distances D6 and a fixed horizontal distance equal to a width of one semiconductor device 502* plus two horizontal distances D7. In each of the first, second, third and fourth sub-semiconductor device arrangements, the minimum distance between two adjacent semiconductor devices is larger than 3 μm.

FIG. 8B is a top view of a partial semiconductor device arrangement according to another embodiment of the present disclosure. The semiconductor device arrangement 6000 is similar with the aforementioned semiconductor device arrangement 1000/1000*. A plurality of semiconductor devices 602, 602′, and 602″ marked with the different background colors is arranged in an array on a carrier (no shown). In the figure, the semiconductor devices 602 are designated as a first group, the semiconductor devices 602′ are designated as a second group, and the semiconductor devices 602″ are designated as a third group. The semiconductor devices 602, 602′, and 602″ may be epitaxially grown on the carrier or fixed on the carrier by an adhesive layer. The details thereof may be referred to the aforementioned figures and paragraphs related to the semiconductor device 102 or 202. The number of each group of semiconductor devices 602, 602′, 602″ is approximately one-third of the total number of all semiconductor devices on the semiconductor device arrangement 6000. Taking advantage of the semiconductor device arrangement 6000, the semiconductor devices 602, 602′, and 602″ may be respectively transferred by contact mode laser transfer processes to different substrates to form different sub-semiconductor device arrangements for the application of the following non-contact mode laser transfer process. For example, the semiconductor devices 602 are collectively transferred as a group to a first substrate (not shown) to form a first sub-semiconductor device arrangement (not shown), the semiconductor devices 602′ are collectively transferred as a group to a second substrate (not shown) to form a second sub-semiconductor device arrangement (not shown), and the semiconductor devices 602″ are left on the original carrier to form a third sub-semiconductor device arrangement (not shown). In the first sub-semiconductor device arrangement, the minimum distance (not shown) is located between two interior angles of two semiconductor devices 602 which are obliquely adjacent to each other, and the minimum distance is larger than the vertical distance D4′ and the horizontal distance D5′. In the second sub-semiconductor device arrangement, the minimum distance (not shown) is located between two interior angles of two semiconductor devices 602′ which are obliquely adjacent to each other. In the third sub-semiconductor device arrangement, the minimum distance (not shown) is located between two interior angles of two semiconductor devices 602″ which are obliquely adjacent to each other. Each of the aforementioned minimum distances is larger than the vertical distance D4′ and the horizontal distance D5′.

It should be understood that the above-mentioned embodiments in the present disclosure may be combined or replaced with each other under appropriate circumstances, and are not limited to the specific embodiments described. For example, in the various embodiments described above, the semiconductor device may or may not include a growth substrate.

Although some embodiments of the present disclosure and their advantages have been described in detail, various changes, substitutions and alterations may be made herein without departing from the spirit and scope of the disclosure as defined by the appended claims.

What is claimed is:

1. A semiconductor device arrangement, comprising:
a substrate, comprising an upper surface; and
a plurality of semiconductor devices separately and staggered arranged on the upper surface and comprising a first semiconductor device and a second semiconductor;
wherein the first semiconductor device comprises a first interior angle and the second semiconductor device comprises a second interior angle;
wherein there is a first minimum distance between the first interior angle and the second interior angle and the first minimum distance is between 3 μm and 25 μm.

2. The semiconductor device arrangement according to claim 1, wherein the first minimum distance is 3 μm, 4 μm, 6 μm, 9 μm, 15 μm, 20 μm, or 25 μm.

3. The semiconductor device arrangement according to claim 1, wherein plurality of semiconductor devices is epitaxially formed on the substrate equidistantly.

4. The semiconductor device arrangement according to claim 1, further comprising an adhesive layer located on the upper surface and the plurality of semiconductor devices is arranged on the adhesive layer.

5. The semiconductor device arrangement according to claim 4, wherein the adhesive layer comprises a plurality of sub-adhesive layers, and plurality of semiconductors is arranged one-to-one on the plurality of sub-adhesive layers.

6. The semiconductor device arrangement according to claim 1, wherein the first interior angle and/or the second interior angle is arc-shaped.

7. The semiconductor device arrangement according to claim 1, wherein the first semiconductor device and the semiconductor device emit a same color light.

8. The semiconductor device arrangement according to claim 1, there is no any semiconductor device existed between the first interior angle and the second interior angle.

9. The semiconductor device arrangement according to claim 1, wherein the first semiconductor device comprises a semiconductor stack, a first electrode, and a second electrode, and the first electrode and the second electrode are located at a same side of the semiconductor stack.

10. The semiconductor device arrangement according to claim 1, wherein the first semiconductor device comprises a semiconductor stack, a first electrode, and a second electrode, and the first electrode and the second electrode are located at a same side of the semiconductor stack.

11. The semiconductor device arrangement according to claim 1, wherein the first semiconductor device comprises a semiconductor stack, a first electrode, and a second electrode, and the first electrode and the second electrode are located opposite sides of the semiconductor stack.

12. The semiconductor device arrangement according to claim 11, wherein the first semiconductor device further comprises a light-translucent conductive layer formed on one surface of the semiconductor stack.

13. The semiconductor device arrangement according to claim 11, the semiconductor device further comprising a concave-convex patent on one side of the semiconductor stack.

14. The semiconductor device arrangement according to claim 1, in a top view, wherein the first semiconductor device comprises a first side, the second semiconductor device comprises a second side, and the first side is parallel to the second side.

15. The semiconductor device arrangement according to claim 14, wherein there is a second maximum distance between the first side and the second side, and the second minimum distance is smaller than the first minimum distance.

16. The semiconductor device arrangement according to claim 9, wherein there is a second maximum distance between the first sidewall and the second sidewall, and the second minimum distance is smaller than 3 μm.

17. The semiconductor device arrangement according to claim 1, in a top view, the first semiconductor device is square, round, rectangular, polygonal or parallelogram.

18. The semiconductor device arrangement according to claim 1, wherein the first semiconductor device is a light-emitting diode, a laser diode, a transistor, or an integrated circuit chip.

19. The semiconductor device arrangement according to claim 1, wherein the first semiconductor device does not have a complete structure.

20. The semiconductor device arrangement according to claim 1, wherein the substrate comprises a flat edge for orientation identification.
